(19) United States
(12) Patent Application Publication
(10) Pub. No.: US 2016/0381805 A1
(43) Pub. Date: Dec. 29, 2016

(54) COPPER FOIL WITH CARRIER, LAMINATE, PRINTED WIRING BOARD, AND METHOD OF PRODUCING ELECTRONIC DEVICES

(71) Applicant: JX NIPPON MINING & METALS CORPORATION, Tokyo (JP)

(72) Inventors: YOSHIYUKI MIYOSHI, IBARAKI (JP); MICHIYA KOHIKI, IBARAKI (JP); TOMOTA NAGAURA, IBARAKI (JP)

(21) Appl. No.: 15/188,255

(22) Filed: Jun. 21, 2016

(30) Foreign Application Priority Data
Jun. 24, 2015 (JP) 2015-127132

(51) Int. Cl. H05K 3/20; B29C 65/72; H05K 1/11; H05K 1/09; H05K 3/00

(52) U.S. Cl. CPC H05K 3/20; H05K 1/09; H05K 3/007; H05K 1/115; B29C 65/72

(57) ABSTRACT

The present invention provides a copper foil with a carrier including an ultra-thin copper layer having a thickness of 0.9 μm or less and capable of preferably preventing generation of pin holes during peeling of the carrier. A copper foil with a carrier including a carrier, an intermediate layer, and an ultra-thin copper layer in this order, wherein the ultra-thin copper layer has a thickness of 0.9 μm or less, and the releasing strength during peeling of the carrier by a 90° releasing method according to JIS C 6471 8.1 is 10 N/m or less.

### BACKGROUND OF THE INVENTION

### Field of the Invention

The present invention relates to copper foils with a carrier, laminates, printed wiring boards, and methods of producing electronic devices, and particularly relates to extremely thin copper foils with a carrier including an ultra-thin copper layer having a thickness of 0.9 μm or less, laminates, printed wiring boards, and methods of producing electronic devices.

### Description of the Related Art

Printed wiring boards are usually produced through the following process: an insulating substrate is bonded onto a copper foil to prepare a copper clad laminate board, and the surface of the copper foil is then etched into a conductive pattern. Recent needs for miniaturization of electronic devices and an increase in their performance have promoted an increase in packaging density of components mounted on these devices and an increase in frequency of signals. Thus, printed wiring boards should satisfy requirements such as a further reduction in pitch of the conductive pattern (finer pitches) and an increase in frequency of signals.

For finer pitches, copper foils having a thickness of 9 μm or less, or 5 μm or less have recently been required. Such extremely thin copper foils have low mechanical strength to readily break or wrinkle during production of printed wiring boards. Accordingly, a copper foil with a carrier, wherein a thick metal foil is adopted as the carrier and an ultra-thin copper layer is electrodeposited on the carrier via a releasing layer between them, has been proposed. The surface of the ultra-thin copper layer is laminated and hot-pressed to an insulating substrate and then the carrier is peeled off via the releasing layer. A resist is formed into a circuit pattern on the exposed ultra-thin copper layer. The ultra-thin copper layer is then removed through etching using an etchant of sulfuric acid-hydrogen peroxide (modified semi-additive process, MSAP) to form a microfine circuit.

Examples of techniques of preventing generation of pin holes in the ultra-thin copper layer of the copper foil with a carrier include those described in Japanese Patent Laid-Open Nos. 2004-169181 and 2005-076091.

Research and development of so-called extremely thin copper foils with a carrier have been progressed, in which the thickness of the ultra-thin copper layer is reduced to 0.9 μm or less. Unfortunately, in such extremely thin copper foils with a carrier, the ultra-thin copper layer, due to its thickness of 0.9 μm or less, is partially peeled with the carrier during peeling of the carrier to generate pin holes in the remaining ultra-thin copper layer. An object of the present invention is to provide a copper foil with a carrier including an ultra-thin copper layer having a thickness of 0.9 μm or less and capable of preferably preventing generation of pin holes during peeling of the carrier.

### SUMMARY OF THE INVENTION

To achieve the above goal, the present inventor has found that in a copper foil with a carrier including an ultra-thin copper layer having a thickness of 0.9 μm or less, generation of pin holes during peeling of the carrier can be preferably prevented through optimization of the releasing strength during peeling of the carrier.

The present invention has been completed based on this knowledge. One aspect according to the present invention is a copper foil with a carrier including a carrier, an intermediate layer, and an ultra-thin copper layer in this order, wherein the ultra-thin copper layer has a thickness of 0.9 μm or less, and the releasing strength during peeling of the carrier by a 90° releasing method according to JIS C 6471 8.1 is 10 N/m or less.

In one embodiment of the copper foil with a carrier according to the present invention, the releasing strength during peeling of the carrier by a 90° releasing method according to JIS C 6471 8.1 is 3 to 10 N/m.

In another embodiment of the copper foil with a carrier according to the present invention, the releasing strength during peeling of the carrier by a 90° releasing method according to JIS C 6471 8.1 is 3 to 9 N/m.

In yet another embodiment of the copper foil with a carrier according to the present invention, the releasing strength during peeling of the carrier by a 90° releasing method according to JIS C 6471 8.1 is 3 to 8 N/m.

In yet another embodiment of the copper foil with a carrier according to the present invention, the ultra-thin copper layer has a thickness of 0.05 to 0.9 μm.

In yet another embodiment of the copper foil with a carrier according to the present invention, the ultra-thin copper layer has a thickness of 0.1 to 0.9 μm.

In yet another embodiment of the copper foil with a carrier according to the present invention, the ultra-thin copper layer has a thickness of 0.85 μm or less.

In yet another embodiment of the copper foil with a carrier according to the present invention, the number of pin holes per unit area (m²) of the ultra-thin copper layer (pin holes/m²) is 20 pin holes/m² or less.

In yet another embodiment of the copper foil with a carrier according to the present invention, if the ultra-thin copper layer is disposed on one surface of the carrier in the copper foil with a carrier according to the present invention, one or more layers selected from the group consisting of a roughened layer, a heat-resistant layer, an anti-corrosive layer, a chromate treated layer, and a silane coupling treated layer are disposed on one surface or both surfaces close to the ultra-thin copper layer and close to the carrier, or if the ultra-thin copper layer is disposed on both surfaces of the carrier in the copper foil with a carrier according to the present invention, one or more layers selected from the group consisting of a roughened layer, a heat-resistant layer, an anti-corrosive layer, a chromate treated layer, and a silane coupling treated layer are disposed on the surface of the ultra-thin copper layer on at least one of both surfaces.

In yet another embodiment of the copper foil with a carrier according to the present invention, at least one of the anti-corrosive layer and the heat-resistant layer contains one or more elements selected from nickel, cobalt, copper, and zinc.

In yet another embodiment of the copper foil with a carrier according to the present invention, the ultra-thin copper layer has a resin layer thereon.

In yet another embodiment of the copper foil with a carrier according to the present invention, the one or more layers selected from a roughened layer, a heat-resistant layer, an anti-corrosive layer, a chromate treated layer, and a silane coupling treated layer have a resin layer thereon.

In yet another embodiment of the copper foil with a carrier according to the present invention, the resin layer contains a dielectric substance.

Another aspect according to the present invention is a printed wiring board produced using the copper foil with a carrier according to the present invention.

Yet another aspect according to the present invention is a laminate produced using the copper foil with a carrier according to the present invention.

Further another aspect according to the present invention is a laminate including the copper foil with a carrier according to the present invention and a resin, wherein end surfaces of the copper foil with a carrier are partially or completely covered with the resin.

Further another aspect according to the present invention is a laminate including two copper foils with a carrier according to the present invention, wherein the carrier or the ultra-thin copper layer of one of the copper foils with a carrier is laminated on the carrier or the ultra-thin copper layer of the other copper foil with a carrier.

Yet another aspect according to the present invention is a method of producing a printed wiring board using the laminate according to the present invention.

Yet another aspect according to the present invention is a method of producing a printed wiring board, comprising:

a step of disposing at least one layer group composed of a resin layer and a circuit on the laminate according to the present invention, and

a step of peeling the ultra-thin copper layer or the carrier from the copper foil with a carrier of the laminate after formation of the at least one layer group composed of a resin layer and a circuit.

Further another aspect according to the present invention is a method of producing a printed wiring board, comprising:

a step of providing the copper foil with a carrier according to the present invention and an insulating substrate,

a step of laminating the copper foil with a carrier on the insulating substrate,

a step of peeling the copper carrier of the copper foil with a carrier to form a copper clad laminate board after lamination of the copper foil with a carrier on the insulating substrate, and

a step of forming a circuit by one of a semi-additive process, a subtractive process, a partly additive process, and a modified semi-additive process.

Further another aspect according to the present invention is a method of producing a printed wiring board, comprising:

a step of forming a circuit on the surface close to the ultra-thin copper layer or the carrier of the copper foil with a carrier according to the present invention,

a step of forming a resin layer on the surface close to the ultra-thin copper layer or the carrier of the copper foil with a carrier such that the circuit is embedded,

a step of peeling the carrier or the ultra-thin copper layer, and

a step of removing the ultra-thin copper layer or the carrier after peeling of the carrier or the ultra-thin copper layer to expose the circuit formed on the surface close to the ultra-thin copper layer or the carrier of the copper foil with a carrier and embedded in the resin layer.

Further another aspect according to the present invention is a method of producing a printed wiring board, comprising:

a step of laminating the surface close to the ultra-thin copper layer or the carrier of the copper foil with a carrier according to the present invention on a resin substrate,

a step of disposing at least one layer group composed of a resin layer and a circuit on the surface close to the ultra-thin copper layer or the carrier of the copper foil with a carrier opposite to the surface thereof laminated on the resin substrate, and

a step of peeling the carrier or the ultra-thin copper layer from the copper foil with a carrier after formation of the at least one layer group composed of a resin layer and a circuit.

Yet another aspect according to the present invention is an electronic device produced using the printed wiring board produced by the method of producing a printed wiring board according to the present invention.

The present invention can provide a copper foil with a carrier including an ultra-thin copper layer having a thickness of 0.9 μm or less and capable of preferably preventing generation of pin holes during peeling of the carrier.

### BRIEF DESCRIPTION OF THE DRAWINGS

FIGS. 1A to 1C are schematic cross-sectional views of a wiring board subjected to steps through a step of plating a circuit and removing a resist in a specific example of the method of producing a printed wiring board using the copper foil with a carrier according to the present invention;

FIGS. 2D to 2F are schematic cross-sectional views of the wiring board subjected to a step of laminating a resin and a second copper foil with a carrier through a step of laser drilling in a specific example of the method of producing a printed wiring board using the copper foil with a carrier according to the present invention;

FIGS. 3G to 3I are schematic cross-sectional views of the wiring board subjected to a step of forming a via fill through a step of peeling a first carrier in a specific example of the method of producing a printed wiring board using the copper foil with a carrier according to the present invention; and

FIGS. 4J to 4K are schematic cross-sectional views of the wiring board subjected to a step of performing flash etching through a step of forming bumps and copper pillars in a specific example of the method of producing a printed wiring board using the copper foil with a carrier according to the present invention.

### DETAILED DESCRIPTION OF THE PREFERRED EMBODIMENTS

<Copper Foil with Carrier>

The copper foil with a carrier according to the present invention includes a carrier, an intermediate layer, and an ultra-thin copper layer in this order. The intermediate layer and the ultra-thin copper layer may be disposed on at least one of both surfaces of the carrier. The ultra-thin copper layer on one surface of the carrier and the other surface of the carrier or the ultra-thin copper layer on both surface of the carrier may be surface treated by roughening. The copper foil with a carrier can be used by any method well known to persons skilled in the art. For example, the surface of the ultra-thin copper layer is laminated and hot-pressed to an insulating substrate or a film composed of a paper-based phenol resin, a paper-based epoxy resin, a synthetic fiber cloth-based epoxy resin, a glass cloth/paper composite based epoxy resin, a glass cloth/glass non-woven fabric composite based epoxy resin, a glass cloth-based epoxy resin, a polyester film, a polyimide film, a liquid crystal polymer, or a fluorinated resin. The carrier is then peeled, and the ultra-thin copper layer bonded onto the insulating substrate is etched into a target conductive pattern. A final product laminate (such as a copper clad laminate) or printed wiring board can be thereby produced.

In the copper foil with a carrier according to the present invention, the releasing strength during peeling of the carrier by a 90° releasing method according to JIS C 6471 8.1 is controlled to 10 N/m or less. Control of the releasing strength during peeling of the carrier by the 90° releasing method according to JIS C 6471 8.1 to 10 N/m or less can preferably prevent generation of pin holes during peeling of the carrier in the so-called extremely thin copper foil with a carrier including an ultra-thin copper layer having a thickness of 0.9 μm or less. If the releasing strength during peeling of the carrier by the 90° releasing method according to JIS C 6471 8.1 is more than 10 N/m, the ultra-thin copper layer is partially peeled with the carrier during peeling of the carrier to generate pin holes in the peeled portions of the ultra-thin copper layer. Excessively low releasing strength between the carrier and the ultra-thin copper layer may result in poor adhesiveness therebetween. From these viewpoints, in the copper foil with a carrier according to the present invention, the releasing strength during peeling of the carrier by the 90° releasing method according to JIS C 6471 8.1 is controlled to preferably 3 to 10 N/m, more preferably 3 to 9 N/m, more preferably 3 to 8 N/m, still more preferably 3 to 5 N/m.

### <Carrier>

The carrier usable in the present invention is a metal foil or a resin film and provided in the form of a copper foil, a copper alloy foil, a nickel foil, a nickel alloy foil, an iron foil, an iron alloy foil, a stainless steel foil, an aluminum foil, or an aluminum alloy foil, an insulating resin film, a polyimide film, a liquid crystal polymer (LCP) film, a fluorinated resin film, a polyamide film, or a PET film, for example. The carrier usable in the present invention is typically provided in the form of a rolled copper foil or an electrodeposited copper foil. Usually, the electrodeposited copper foil is produced as follows: Copper is deposited on a drum of titanium or stainless steel in a copper sulfate plating bath by electrolysis. The rolled copper foil is produced through repeated plastic forming with a rolling roll and heat treatment. Examples of usable materials for the copper foil include high purity copper such as tough-pitch copper (JIS H3100 alloy No. C1100) and oxygen-free copper (JIS H3100 alloy No. C1020 or JIS H3510 alloy No. C1011), and copper alloys such as Sn containing copper, Ag containing copper, copper alloys containing Cr, Zr, or Mg, and Corson copper alloys containing Ni and Si. Through the specification, the term “copper foil” used alone includes copper alloy foils.

The carrier usable in the present invention has any thickness. The thickness may be appropriately adjusted to serve as a carrier, for example, 5 μm or more. An excessively large thickness increases production cost. The thickness is preferably 35 μm or less in general. Thus, the thickness of the carrier is typically 8 to 70 μm, more typically 12 to 70 μm, more typically 18 to 35 μm. The carrier preferably has a small thickness to reduce cost of raw materials. For this reason, the thickness of the carrier is typically 5 μm or more and 35 μm or less, preferably 5 μm or more and 18 μm or less, preferably 5 μm or more and 12 μm or less, preferably 5 μm or more and 11 μm or less, preferably 5 μm or more and 10 μm or less. A carrier having a small thickness readily bends and wrinkles during feeding of the carrier. For example, a smooth conveying roll for an apparatus for producing a copper foil with a carrier and a short distance between the conveying roll and the following conveying roll are effective in preventing bend and wrinkle.

An example of conditions on production using an electrodeposited copper foil as a carrier is shown as follows.

### <Composition of Electrolyte Solution>

Copper: 90 to 110 g/L

Sulfuric acid: 90 to 110 g/L

Chlorine: 50 to 100 ppm

Leveling agent 1 (bis(3-sulfopropyl)disulfide): 10 to 30 ppm

Leveling agent 2 (amine compound): 10 to 30 ppm

Examples of the amine compound usable include an amine compound represented by the following formula.

The electrolyte solution and the plating solution described in the present invention contain water as the rest of the composition, unless otherwise specified.

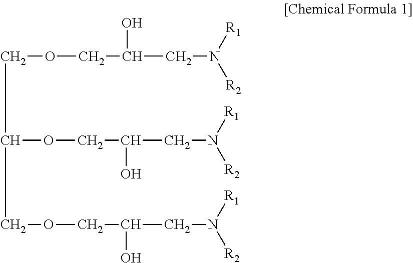

where R₁ and R₂ represent a group selected from the group consisting of a hydroxyalkyl group, an ether group, an aryl group, an aromatic substituted alkyl group, an unsaturated hydrocarbon group, and an alkyl group.

### <Conditions on Production>

Current density: 70 to 100 A/dm²

Temperature of electrolyte solution: 50 to 60° C.

Linear velocity of electrolyte solution: 3 to 5 m/sec

Electrolysis time: 0.5 to 10 minutes

### <Intermediate Layer>

An intermediate layer is disposed on one or both surfaces of the carrier. An additional layer may be disposed between the copper foil carrier and the intermediate layer. Any intermediate layer can be used in the present invention as long as the intermediate layer prevents peeling of the ultra-thin copper layer from the carrier before lamination of the copper foil with a carrier on an insulating substrate while enabling peeling of the ultra-thin copper layer from the carrier after lamination of the copper foil with a carrier on the insulating substrate. For example, the intermediate layer in the copper foil with a carrier according to the present invention may contain one or two or more selected from the group consisting of Cr, Ni, Co, Fe, Mo, Ti, W, P, Cu, Al, and Zn, alloys thereof, hydrates thereof, oxides thereof, and organic products thereof. The intermediate layer may be composed of a plurality of sublayers.

For example, the intermediate layer can be formed as follows: A layer is formed on the carrier, the layer being a metal monolayer consisting of one element selected from the group consisting of Cr, Ni, Co, Fe, Mo, Ti, W, P, Cu, Al, and Zn, an alloy layer consisting of one or two or more elements selected from the group consisting of Cr, Ni, Co, Fe, Mo, Ti, W, P, Cu, Al, and Zn, or an organic product layer. A layer consisting of a hydrate, an oxide, or an organic product of one or two or more elements selected from the group consisting of Cr, Ni, Co, Fe, Mo, Ti, W, P, Cu, Al, and Zn is formed on the layer.

For example, the intermediate layer can be formed as follows: A layer is formed on the carrier, the layer being a metal monolayer consisting of one element selected from the group consisting of Cr, Ni, Co, Fe, Mo, Ti, W, P, Cu, Al, and Zn, an alloy layer consisting of one or more elements selected from the group consisting of Cr, Ni, Co, Fe, Mo, Ti, W, P, Cu, Al, and Zn, or a layer consisting of an organic product. Then, a metal monolayer consisting of one element selected from the group consisting of Cr, Ni, Co, Fe, Mo, Ti, W, P, Cu, Al, and Zn or an alloy layer consisting of one or more elements selected from the group consisting of Cr, Ni, Co, Fe, Mo, Ti, W, P, Cu, Al, and Zn is formed. The additional layer may have a layer configuration which can be used as the intermediate layer.

If the intermediate layer is disposed only on one surface of the carrier, a roughened layer or an anti-corrosive layer such as a Ni-plated layer is preferably disposed on the other surface of the carrier. If the intermediate layer is disposed by a chromate treatment, a zinc chromate treatment, or plating, it is considered that part of the metal deposited, such as chromium or zinc, may be a hydrate or an oxide thereof.

For example, the intermediate layer can be composed of nickel, a nickel-phosphorus alloy, or a nickel-cobalt alloy and chromium containing layer laminated on the carrier in this order. The adhesive force between nickel and copper is greater than that between chromium and copper. As a result, the ultra-thin copper layer is peeled at the interface between the ultra-thin copper layer and chromium. A barrier effect of nickel in the intermediate layer is expected to prevent diffusion of the copper component from the carrier to the ultra-thin copper layer. A preferred chromium containing layer is a chromate treated layer or chromium layer or a chromium alloy layer. Throughout the specification, the chromate treated layer indicates a layer treated with a solution containing chromic acid anhydride, chromic acid, dichromic acid, chromate, or dichromate. The chromate treated layer may contain an element such as Co, Fe, Ni, Mo, Zn, Ta, Cu, Al, P, W, Mn, Sn, As, and Ti (which may have any form such as metal, alloy, oxide, nitride, or sulfide). Specific examples of the chromate treated layer include pure chromate treated layers and zinc chromate treated layers. In the present invention, the pure chromate treated layer indicates a chromate treated layer treated with an aqueous solution of chromic acid anhydride or potassium dichromate. In the present invention, the zinc chromate treated layer indicates a chromate treated layer treated with a treatment solution containing chromic acid anhydride or potassium dichromate and zinc. The amount of nickel applied in the intermediate layer is preferably 100 μg/dm² or more and 40000 μg/dm² or less, more preferably 200 μg/dm² or more and 30000 μg/dm² or less, more preferably 300 μg/dm² or more and 20000 μg/dm² or less, more preferably 400 μg/dm² or more and less than 15000 μg/dm². The amount of chromium applied in the intermediate layer is preferably 5 μg/dm² or more and 150 μg/dm² or less, preferably 5 μg/dm² or more and 100 μg/dm² or less.

The organic product contained in the intermediate layer is preferably one or more organic products selected from the group consisting of nitrogen containing organic compounds, sulfur containing organic compounds, and carboxylic acids. Specific examples of nitrogen containing organic compounds preferably used include triazole compounds having substituents, such as 1,2,3-benzotriazole, carboxybenzotriazole, N′,N′-bis(benzotriazolylmethyl)urea, 1H-1,2,4-triazole, and 3-amino-1H-1,2,4-triazole.

Examples of the sulfur containing organic compounds preferably used include mercaptobenzothiazole, sodium 2-mercaptobenzothiazole, thiocyanuric acid, and 2-benzimidazolethiol.

Carboxylic acids particularly preferably used are monocarboxylic acids. Among these monocarboxylic acids, oleic acid, linolic acid, and linoleic acid are preferably used.

The organic product is contained in a thickness of preferably 5 nm or more and 80 nm or less, more preferably 10 nm or more and 70 nm or less. The intermediate layer may contain several (one or more) organic products described above.

The thickness of the organic product can be measured as follows.

### <Thickness of Organic Product in Intermediate Layer>

The ultra-thin copper layer of the copper foil with a carrier is peeled from the carrier. The surface close to the intermediate layer of the exposed ultra-thin copper layer and the surface close to the intermediate layer of the exposed carrier are then measured by XPS to create depth profiles. The initial depth from the surface close to the intermediate layer of the ultra-thin copper layer at a carbon content of 3 at % or less is defined as A (nm), and the initial depth from the surface close to the intermediate layer of the carrier at a carbon content of 3 at % or less is defined as B (nm). The sum of A and B can be defined as the thickness (nm) of the organic product in the intermediate layer.

The XPS is performed on the following conditions:
Apparatus: XPS instrument (ULVAC-PHI, Inc., Type 5600MC)
Ultimate vacuum: 3.8×10⁻⁷ Pa
X rays: monochromatic AlKα or non-monochromatic MgKα, X-ray output: 300 W, detected area: 800 μmφ, angle formed by the sample and the detector: 45°
Ion beams: ion type: Ar^{t}, accelerating voltage: 3 kV, sweeping area: 3 mm×3 mm, sputtering rate: 2.8 nm/min (in terms of SiO₂)

### <Ultra-Thin Copper Layer>

An ultra-thin copper layer is disposed on the intermediate layer. An additional layer may be disposed between the intermediate layer and the ultra-thin copper layer. The ultra-thin copper layer may be disposed on both surfaces of the carrier. The ultra-thin copper layer may be an electrodeposited copper layer. Throughout the specification, the electrodeposited copper layer indicates a copper layer formed by electroplating (electrolytic plating). The ultra-thin copper layer can be formed through electric plating with an electrolytic bath using copper sulfate, copper pyrophosphate, copper sulfamate, or copper cyanide. A copper sulfate bath is preferred because it is used in preparation of common electrodeposited copper foils and can form copper foils with high current density. The plating solution used in formation of the ultra-thin copper layer may contain a gloss agent. The thickness of the ultra-thin copper layer is controlled to 0.9 μm or less. Such a configuration enables an extremely fine circuit to be formed with the ultra-thin copper layer. Higher circuit formability can be attained by a smaller thickness of the ultra-thin copper layer. Accordingly, the thickness is preferably 0.85 μm or less, more preferably 0.80 μm or less, still more preferably 0.75 μm or less, still more preferably 0.70 μm or less, still more preferably 0.65 μm or less, still more preferably 0.60 μm or less, still more preferably 0.50 μm or less, still more preferably 0.45 μm or less, still more preferably 0.40 μm or less, still more preferably 0.35 μm or less, still more preferably 0.32 μm or less, still more preferably 0.30 μm or less, still more preferably 0.25 μm or less. An extremely small thickness of the ultra-thin copper layer may cause difficulties in handling. Accordingly, the thickness is preferably 0.01 μm or more, more preferably 0.05 μm or more, more preferably 0.10 μm or more, still more preferably 0.15 μm or more. The thickness of the ultra-thin copper layer is typically 0.01 to 0.9 μm, typically 0.05 to 0.9 μm, more typically 0.1 to 0.9 μm, still more typically 0.15 to 0.9 μm.

The pin holes generated in the ultra-thin copper layer may cause disconnection of the circuit. For this reason, a reduction in the number of pin holes in the ultra-thin copper layer is desirable.

The number of pin holes per unit area (m²) of the ultra-thin copper layer (pin holes/m²) is preferably 20 pin holes/m² or less, preferably 15 pin holes/m² or less, preferably 11 pin holes/m² or less, preferably 10 pin holes/m² or less, preferably 8 pin holes/m² or less, preferably 6 pin holes/m² or less, preferably 5 pin holes/m² or less, preferably 3 pin holes/m² or less, preferably 1 pin hole/m² or less, preferably 1 pin hole/m² or less, preferably 0 pin holes/m².

### <Roughening and Other Surface Treatments>

A roughened layer may be disposed through roughening of one or both of the surface of the ultra-thin copper layer and the surface of the carrier to enhance the adhesion with an insulating substrate, for example. The roughening treatment can be performed through formation of roughening particles of copper or a copper alloy, for example. Fine roughening may be performed. The roughened layer may consist of a single substance selected from the group consisting of copper, nickel, cobalt, phosphorus, tungsten, arsenic, molybdenum, chromium, and zinc, or may consist of an alloy containing one or more elements selected therefrom. An alternative roughening treatment can also be performed: Roughening particles of copper or a copper alloy are formed, and secondary particles and/or tertiary particles of a single substance or an alloy selected from nickel, cobalt, copper, and zinc are then disposed. Subsequently, a heat-resistant layer and/or an anti-corrosive layer may be formed with a single substance or an alloy selected from nickel, cobalt, copper, and zinc, and the surface of the resulting layer may be subjected to a chromate treatment or a silane coupling treatment. Alternatively, without a roughening treatment, a heat-resistant layer and/or an anti-corrosive layer may be formed with a single substance or an alloy selected from nickel, cobalt, copper, and zinc, and the surface of the resulting layer may be subjected to a chromate treatment or a silane coupling treatment. Namely, one or more layers selected from the group consisting of a heat-resistant layer, an anti-corrosive layer, a chromate treated layer, and a silane coupling treated layer may be formed on the surface of the roughened layer. One or more layers selected from the group consisting of a heat-resistant layer, an anti-corrosive layer, a chromate treated layer, and a silane coupling treated layer may be formed on the surface of the ultra-thin copper layer. The heat-resistant layer, the anti-corrosive layer, the chromate treated layer, and the silane coupling treated layer may be formed of a plurality of sublayers (for example, two or more sublayers, or three or more sublayers).

Throughout the specification, the chromate treated layer indicates a layer treated with a solution containing chromic acid anhydride, chromic acid, dichromic acid, chromate, or dichromate. The chromate treated layer may contain an element such as cobalt, iron, nickel, molybdenum, zinc, tantalum, copper, aluminum, phosphorus, tungsten, tin, arsenic, and titanium (which may have any form such as metal, alloy, oxide, nitride, or sulfide). Specific examples of the chromate treated layer include chromate treated layers treated with an aqueous solution of chromic acid anhydride or potassium dichromate, and chromate treated layers treated with a treatment solution containing chromic acid anhydride or potassium dichromate and zinc.

A roughened layer disposed on the surface of the carrier opposite to the surface on which the ultra-thin copper layer is to be disposed is advantageous in that peeling of the carrier and the resin substrate is prevented through lamination of the surface of the carrier including the roughened layer on a support such as a resin substrate. Formation of the surface treated layer such as a heat-resistant layer further on the roughened layer on the surface of the ultra-thin copper layer or the carrier, as described above, can preferably prevent diffusion of an element such as copper from the ultra-thin copper layer or the carrier to the corresponding resin base. As a result, the ultra-thin copper layer or the carrier is laminated on the resin base by hot pressing with enhanced adhesion.

Any known heat-resistant layer and anti-corrosive layer can be used. For example, the heat-resistant layer and/or the anti-corrosive layer may contain one or more elements selected from the group consisting of nickel, zinc, tin, cobalt, molybdenum, copper, tungsten, phosphorus, arsenic, chromium, vanadium, titanium, aluminum, gold, silver, platinum group metals, iron, and tantalum; or the heat-resistant layer and/or the anti-corrosive layer may be a metal layer or an alloy layer consisting of one or more elements selected from the group consisting of nickel, zinc, tin, cobalt, molybdenum, copper, tungsten, phosphorus, arsenic, chromium, vanadium, titanium, aluminum, gold, silver, platinum group metals, iron, and tantalum. The heat-resistant layer and/or the anti-corrosive layer may contain an oxide, a nitride, or a silicide containing the elements listed above. The heat-resistant layer and/or the anti-corrosive layer may contain a nickel-zinc alloy. The heat-resistant layer and/or the anti-corrosive layer may be a nickel-zinc alloy layer. The nickel-zinc alloy layer may contain 50 wt % to 99 wt % of nickel and 50 wt % to 1 wt % of zinc excluding inevitable impurities. The total amount of zinc and nickel applied in the nickel-zinc alloy layer may be 5 to 1000 mg/m², preferably 10 to 500 mg/m², preferably 20 to 100 mg/m². The ratio of the amount of nickel applied to that of zinc applied in the layer containing a nickel-zinc alloy or the nickel-zinc alloy layer (=amount of nickel applied/amount of zinc applied) is preferably 1.5 to 10. The amount of nickel applied in the layer containing a nickel-zinc alloy or the nickel-zinc alloy layer is preferably 0.5 mg /m² to 500 mg/m², more preferably 1 mg/m² to 50 mg/m². If the heat-resistant layer and/or the anti-corrosive layer is a layer containing a nickel-zinc alloy, the adhesion between the copper foil and the resin substrate is enhanced.

For example, the heat-resistant layer and/or the anti-corrosive layer may be a laminate composed of a nickel or nickel alloy layer in an amount applied of 1 mg/m² to 100 mg /m², preferably 5 mg/m² to 50 mg/m² and a tin layer in an amount applied of 1 mg/m² to 80 mg/m², preferably 5 mg/m² to 40 mg/m² sequentially disposed. The nickel alloy layer may be composed of any one of nickel-molybdenum, nickel-zinc, nickel-molybdenum-cobalt, and nickel-tin alloys. In the heat-resistant layer and/or the anti-corrosive layer, [amount of nickel applied or amount of nickel in nickel alloy applied]/[amount of tin applied] is preferably 0.25 to 10, more preferably 0.33 to 3. Use of the heat-resistant layer and/or the anti-corrosive layer enhances the releasing strength of the circuit after the copper foil with a carrier is formed into a printed wiring board, and reduces the deterioration rate of the resistance against chemicals of the releasing strength.

The silane coupling treated layer may be formed with a known silane coupling agent. Examples of the silane coupling agent include epoxysilane coupling agents, aminosilane coupling agents, methacryloxysilane coupling agents, mercaptosilane coupling agents, vinylsilane coupling agents, imidazolesilane coupling agents, and triazinesilane coupling agents. Two or more silane coupling agents can be used as a mixture. Among these silane coupling agents, aminosilane coupling agents or epoxysilane coupling agents are preferably used in formation of the silane coupling treated layer.

The silane coupling treated layer is desirably disposed in the range of 0.05 mg/m² to 200 mg/m², preferably 0.15 mg/m² to 20 mg/m², preferably 0.3 mg/m² to 2.0 mg/m² in terms of silicon atoms. Within this range, the adhesion between the base and the surface treated copper foil can be further enhanced.

The surface of the ultra-thin copper layer, the roughened layer, the heat-resistant layer, the anti-corrosive layer, the silane coupling treated layer, or the chromate treated layer can be subjected to the surface treatment described in WO2008/053878, Japanese Patent Laid-Open No. 2008-111169, Japanese Patent No. 5024930, WO2006/028207, Japanese Patent No. 4828427, WO2006/134868, Japanese Patent No. 5046927, WO2007/105635, Japanese Patent No. 5180815, or Japanese Patent Laid-Open No. 2013-19056.

The copper foil with a carrier according to the present invention may include a resin layer on the ultra-thin copper layer, the roughened layer, the heat-resistant layer, the anti-corrosive layer, the chromate treated layer, or the silane coupling treated layer. The resin layer may be an insulating resin layer.

The resin layer may be an adhesive, or may be a semi-cured (stage B) insulating resin layer for an adhesive. The semi-cured (stage B) state of the insulating resin layer includes the state where the surface of the insulating resin layer is not sticky to the touch when touched by the finger, the insulating resin layers can be layered for storage, and the insulating resin layer is cured through a heat treatment.

The resin layer may contain a thermosetting resin, or may be composed of a thermoplastic resin. The resin layer may contain a thermoplastic resin. Suitable examples of the resins include, but should not be limited to, resins containing one or more selected from the group consisting of epoxy resins, polyimide resins, polyfunctional cyanic acid ester compounds, maleimide compounds, poly(vinyl acetal) resins, urethane resins, polyethersulfone, polyethersulfone resin, aromatic polyamide resins, polyamideimide resins, rubber-modified epoxy resins, phenoxy resins, carboxyl group-modified acrylonitrile-butadiene resins, poly(phenylene oxide), bismaleimide triazine resins, thermosetting poly(phenylene oxide) resins, cyanate ester resins, anhydrides of polyvalent carboxylic acids, linear polymers having crosslinkable functional groups, polyphenylene ether resins, 2,2-bis(4-cyanatophenyl)propane, phosphorus containing phenol compounds, manganese naphthenate, 2,2-bis(4-glycidylphenyl)propane, polyphenylene ether-cyanate resins, siloxane-modified polyamideimide resins, cyano ester resins, phosphazene resins, rubber-modified polyamideimide resins, isoprene, hydrogenated polybutadiene, poly(vinyl butyral), phenoxy resins, polymer epoxy resins, aromatic polyamides, fluorinated resins, bisphenol, block copolymerized polyimide resins, and cyano ester resins.

Any epoxy resin having two or more epoxy groups in the molecule and usable in applications of electrical and electronic materials can be used without limitation. Preferred epoxy resins are those prepared through epoxidation of a compound having two or more glycidyl groups in the molecule. The epoxy resin used can be one or a mixture of two or more selected from the group consisting of bisphenol A epoxy resins, bisphenol F epoxy resins, bisphenol S epoxy resins, bisphenol AD epoxy resins, novolac epoxy resins, cresol novolac epoxy resins, alicyclic epoxy resins, brominated epoxy resins, phenol novolac epoxy resins, naphthalene epoxy resins, brominated bisphenol A epoxy resins, ortho-cresol novolac epoxy resins, rubber-modified bisphenol A epoxy resins, glycidylamine epoxy resins, glycidylamine compounds (such as triglycidyl isocyanurate and N,N-diglycidylaniline), glycidyl ester compounds (such as tetrahydrophthalic acid diglycidyl ester), phosphorus containing epoxy resins, biphenyl epoxy resins, biphenyl novolac epoxy resins, trishydroxyphenylmethane epoxy resins, and tetraphenylethane epoxy resins. Alternatively, hydrogenated or halogenated products of the epoxy resins can be used.

Known epoxy resins containing phosphorus can be used as the phosphorus containing epoxy resins. The phosphorus containing epoxy resins are preferably epoxy resins obtained as derivatives from 9,10-dihydro-9-oxa-10-phosphaphenanthrene 10-oxide having two or more epoxy groups in the molecule, for example.

The resin layer may contain a known resin, a resin curing agent, a compound, a curing accelerator, a dielectric substance (any dielectric substance such as a dielectric substance containing an inorganic compound and/or an organic compound, or a dielectric substance containing a metal oxide may be used), a reaction catalyst, a crosslinking agent, a polymer, a prepreg, a skeleton material, and a resin and a compound described above. The resin layer can be formed using any substance (such as a resin, a resin curing agent, a compound, a curing accelerator, a dielectric substance, a reaction catalyst, a crosslinking agent, a polymer, a prepreg, and a skeleton material) and/or any method of forming a resin layer, and any forming apparatus described in WO2008/004399, WO2008/053878, WO2009/084533, Japanese Patent Laid-Open No. 11-5828, Japanese Patent Laid-Open No. 11-140281, Japanese Patent No. 3184485, WO97/02728, Japanese Patent No. 3676375, Japanese Patent Laid-Open No. 2000-43188, Japanese Patent No. 3612594, Japanese Patent Laid-Open No. 2002-179772, Japanese Patent Laid-Open No. 2002-359444, Japanese Patent Laid-Open No. 2003-304068, Japanese Patent No. 3992225, Japanese Patent Laid-Open No. 2003-249739, Japanese Patent No. 4136509, Japanese Patent Laid-Open No. 2004-82687, Japanese Patent No. 4025177, Japanese Patent Laid-Open No. 2004-349654, Japanese Patent No. 4286060, Japanese Patent Laid-Open No. 2005-262506, Japanese Patent No. 4570070, Japanese Patent Laid-Open No. 2005-53218, Japanese Patent No. 3949676, Japanese Patent No. 4178415, WO2004/005588, Japanese Patent Laid-Open No. 2006-257153, Japanese Patent Laid-Open No. 2007-326923, Japanese Patent Laid-Open No. 2008-111169, Japanese Patent No. 5024930, WO2006/028207, Japanese Patent No. 4828427, Japanese Patent Laid-Open No. 2009-67029, WO2006/134868, Japanese Patent No. 5046927, Japanese Patent Laid-Open No. 2009-173017, WO2007/105635, Japanese Patent No. 5180815, WO2008/114858, WO2009/008471, Japanese Patent Laid-Open No. 2011-14727, WO2009/001850, WO2009/145179, WO2011/068157, and Japanese Patent Laid-Open No. 2013-19056, for example.

### (Cases Where Resin Layer Contains Dielectric Substance (Dielectric Substance Filler))

The resin layer may contain a dielectric substance (dielectric substance filler).

A dielectric substance (dielectric substance filler), if contained in the resin layer or the resin composition, can be used in formation of a capacitor layer to increase the electric capacitance of the capacitor circuit. The dielectric substances (dielectric substance fillers) used are powder of dielectric substances of composite oxides having a perovskite structure, such as BaTiO₃, SrTiO₃, Pb(Zr—Ti)O₃ (known as PZT), PbLaTiO₃.PbLaZrO (known as PLZT), and SrBi₂Ta₂O₉ (known as SBT).

The resin and/or the resin composition and/or the compound contained in the resin layer is dissolved in a solvent such as methyl ethyl ketone (MEK) or toluene to prepare a resin solution. The resin solution is applied onto the ultra-thin copper layer, the heat-resistant layer, the anti-corrosive layer, the chromate coating layer, or the silane coupling agent layer by roll coating. When necessary, the coating is then brought into the stage B state through removal of the solvent by heating and drying. The coating may be dried with a hot air drying furnace. The drying temperature may be 100 to 250° C., preferably 130 to 200° C.

The copper foil with a carrier including the resin layer (resin-coated copper foil with a carrier) is used as follows: The resin layer of a copper foil with a carrier is layered on a base, and then is as a whole hot-pressed to the base to thermally cure the resin layer. The carrier is then peeled to expose the ultra-thin copper layer (the surface close to the intermediate layer of the ultra-thin copper layer should be exposed). A predetermined wiring pattern is formed on the surface of the ultra-thin copper layer.

Use of this resin-coated copper foil with a carrier can reduce the number of prepreg materials used during production of multi-layered printed wiring boards. In addition, the resin layer can have a thickness so as to ensure interlayer insulation. A copper clad laminate board can be produced without any prepreg material. At this time, an insulating resin for an undercoat can also be applied onto the surface of the base to further enhance the smoothness of the surface.

No use of prepreg materials results in a reduction in cost for prepreg materials and a reduction in the number of lamination steps, thus providing economic advantages. Further advantages are that the thickness of the resulting multi-layered printed wiring board can be reduced by the thickness of the prepreg material, thus producing ultra-thin multi-layered printed wiring boards in which a layer has a thickness of 100 μm or less.

The resin layer preferably has a thickness of 0.1 to 80 μm. A thickness of the resin layer of less than 0.1 pm may reduce the adhesive force. As a result, when such a resin-coated copper foil with a carrier is laminated on a base including an inner layer material without any prepreg material being interposed therebetween, the interlayer insulation between the same and the circuit of the inner layer material cannot be ensured in some cases.

At a thickness of the resin layer of more than 80 μm, a resin layer having a target thickness cannot be formed by a single application step. As a result, extra cost for materials and the extra number of steps should be needed, resulting in economic disadvantages. Furthermore, the resulting resin layer has inferior flexibility. For this reason, crack may be readily generated during handling of the resin layer. An excess resin flow may occur during hot-pressing to the inner layer material to obstruct smooth lamination operation.

The resin-coated copper foil with a carrier can also be produced in another form of a product. Namely, the ultra-thin copper layer, the heat-resistant layer, the anti-corrosive layer, the chromate treated layer, or the silane coupling treated layer can be coated with a resin layer. The resin layer is semi-cured. The carrier is then peeled to produce a resin-coated copper foil without a carrier.

Examples of the process of producing a printed wiring board using the copper foil with a carrier according to the present invention will now be described.

One embodiment of the method of producing a printed wiring board according to the present invention comprises a step of providing the copper foil with a carrier according to the present invention and an insulating substrate, a step of laminating the copper foil with a carrier on the insulating substrate, a step of, after lamination of the copper foil with a carrier on the insulating substrate so that the ultra-thin copper layer faces the insulating substrate, peeling the carrier of the copper foil with a carrier to form a copper clad laminate board, and a step of forming a circuit by one of a semi-additive process, a modified semi-additive process, a partly additive process, and a subtractive process. An insulating substrate including an internal circuit can also be used.

In the present invention, the semi-additive process indicates a process of slightly applying non-electrolytic plating on an insulating substrate or a copper foil seed layer, forming a pattern, and then forming a conductive pattern by electroplating and etching.

Accordingly, one embodiment of the method of producing a printed wiring board according to the present invention using the semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of completely removing the ultra-thin copper layer exposed after peeling of the carrier by etching using a corrosive solution of an acid or a method using plasma,

a step of disposing through holes or/and blind via holes in the resin exposed after removal of the ultra-thin copper layer by etching,

a step of desmearing a region including the through holes or/and the blind via holes,

a step of disposing a non-electrolytically plated layer in a region including the resin and the through holes or/and the blind via holes,

a step of disposing a plating resist on the non-electrolytically plated layer,

a step of exposing the plating resist to light, and then removing the plating resist in the region in which a circuit is formed,

a step of disposing an electrolytically plated layer in the region from which the plating resist is removed to form a circuit,

a step of removing the plating resist, and

a step of removing the non-electrolytically plated layer by flash etching, the non-electrolytically plated layer being in a region other than the region in which a circuit is formed.

Another embodiment of the method of producing a printed wiring board according to the present invention using a semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of completely removing the ultra-thin copper layer exposed after peeling of the carrier by etching using a corrosive solution of an acid or a method using plasma,

a step of disposing a non-electrolytically plated layer in a surface of the resin exposed after removal of the ultra-thin copper layer by etching,

a step of disposing a plating resist on the non-electrolytically plated layer,

a step of exposing the plating resist to light, and then removing the plating resist in a region in which a circuit is formed,

a step of disposing an electrolytically plated layer in the region from which the plating resist is removed to form a circuit,

a step of removing the plating resist, and

a step of removing the non-electrolytically plated layer and the ultra-thin copper layer by flash etching, the non-electrolytically plated layer and the ultra-thin copper layer being in a region other than the region in which a circuit is formed.

In the present invention, the modified semi-additive process indicates a process of laminating a metal foil on an insulating layer, protecting a non-circuit-forming portion with a plating resist, forming a thick layer of copper on a circuit-forming portion by electrolytic plating, then removing the resist, and removing the metal foil in a portion other than the circuit-forming portion by (flash) etching to form a circuit on the insulating layer.

Accordingly, one embodiment of the method of producing a printed wiring board according to the present invention using the modified semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of disposing a non-electrolytically plated layer in the region including the through holes or/and the blind via holes,

a step of disposing a plating resist on the surface of the ultra-thin copper layer exposed after peeling of the carrier,

a step of forming a circuit by electrolytic plating after disposition of the plating resist,

a step of removing the plating resist, and

a step of by flash etching, removing the ultra-thin copper layer exposed after removal of the plating resist.

Another embodiment of the method of producing a printed wiring board according to the present invention using the modified semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing a plating resist on the ultra-thin copper layer exposed after peeling of the carrier,

a step of exposing the plating resist to light, and then removing the plating resist in a region in which a circuit is formed,

a step of disposing an electrolytically plated layer in the region from which the plating resist is removed to form a circuit,

a step of removing the plating resist, and

a step of removing the non-electrolytically plated layer and the ultra-thin copper layer by flash etching, the non-electrolytically plated layer and the ultra-thin copper layer being in a region other than the region in which a circuit is formed.

In the present invention, a partly additive process indicates a process of placing catalyst nuclei on a substrate having a conductor layer disposed thereon, when necessary a substrate having holes for through holes or via holes, etching the substrate to form a conductor circuit, when necessary disposing a solder resist or a plating resist, and then forming a thick layer on the conductor circuit, the through holes, and the via holes by a non-electrolytic plating treatment to produce a printed wiring board.

Accordingly, one embodiment of the method of producing a printed wiring board according to the present invention using the partly additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of placing catalyst nuclei in the region including the through holes or/and the blind via holes,

a step of disposing an etching resist on the surface of the ultra-thin copper layer exposed after peeling of the carrier,

a step of exposing the etching resist to light to form a circuit pattern,

a step of removing the ultra-thin copper layer and the catalyst nuclei by etching using a corrosive solution of an acid or a method using plasma to form a circuit,

a step of removing the etching resist,

a step of disposing a solder resist or a plating resist on the surface of the insulating substrate exposed after removal of the ultra-thin copper layer and the catalyst nuclei by etching using a corrosive solution of an acid or a method using plasma, and

a step of disposing a non-electrolytically plated layer in a region in which the solder resist or the plating resist is not disposed.

In the present invention, the subtractive process indicates a process of selectively removing unnecessary portions of the copper foil on a copper clad laminate board by etching to form a conductive pattern.

Accordingly, one embodiment of the method of producing a printed wiring board according to the present invention using the subtractive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of disposing a non-electrolytically plated layer in the region including the through holes or/and the blind via holes,

a step of disposing an electrolytically plated layer on the surface of the non-electrolytically plated layer,

a step of disposing an etching resist on the surface of the electrolytically plated layer or/and the ultra-thin copper layer,

a step of exposing the etching resist to light to form a circuit pattern,

a step of removing the ultra-thin copper layer and the non-electrolytically plated layer and the electrolytically plated layer by etching using a corrosive solution of an acid or by a method using plasma to form a circuit, and

a step of removing the etching resist.

Another embodiment of the method of producing a printed wiring board according to the present invention using the subtractive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of disposing a non-electrolytically plated layer in the region including the through holes or/and the blind via holes,

a step of forming a mask on the surface of the non-electrolytically plated layer,

a step of disposing an electrolytically plated layer on the surface of the non-electrolytically plated layer in which the mask is not formed,

a step of disposing an etching resist on the surface of the electrolytically plated layer or/and the ultra-thin copper layer,

a step of exposing the etching resist to light to form a circuit pattern,

a step of removing the ultra-thin copper layer and the non-electrolytically plated layer by etching using a corrosive solution of an acid or by a method using plasma to form a circuit, and

a step of removing the etching resist.

A step of disposing through holes or/and blind via holes and the subsequent desmearing step may not be performed.

A specific example of the method of producing a printed wiring board using the copper foil with a carrier according to the present invention will now be described in detail by way of the drawings. In description of this example, although a roughened layer is formed on the surface of the ultra-thin copper layer in the copper foil with a carrier, the roughened layer may be optionally formed.

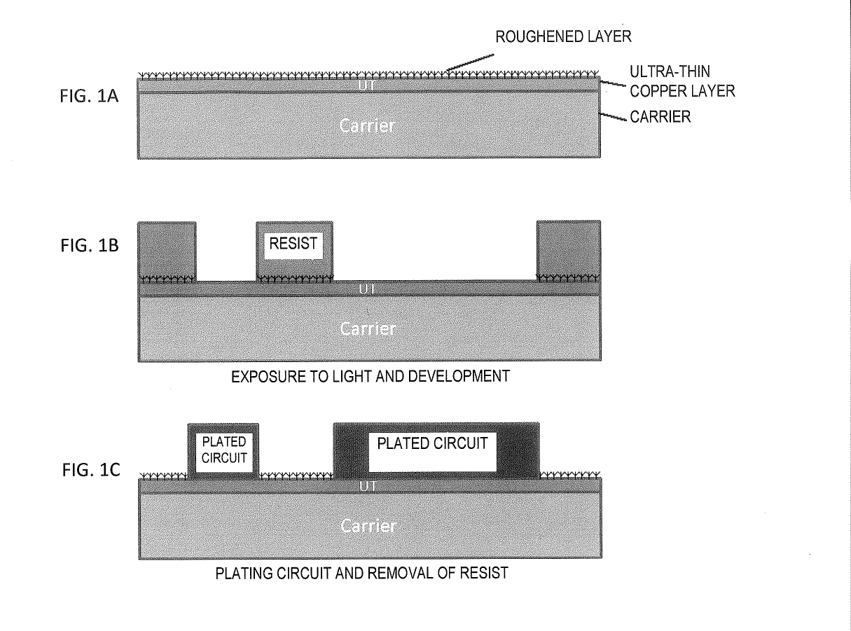

First, as shown in FIG. 1-A, a first copper foil with a carrier (first layer) having an ultra-thin copper layer having a roughened layer formed on the surface thereof is provided.

Next, as shown in FIG. 1-B, a resist is applied onto the roughened layer of the ultra-thin copper layer, and exposure and development are performed to etch the resist into a predetermined shape.

Next, as shown in FIG. 1-C, plating is performed for formation of a circuit, and the resist is removed to form a plated circuit of a predetermined shape.

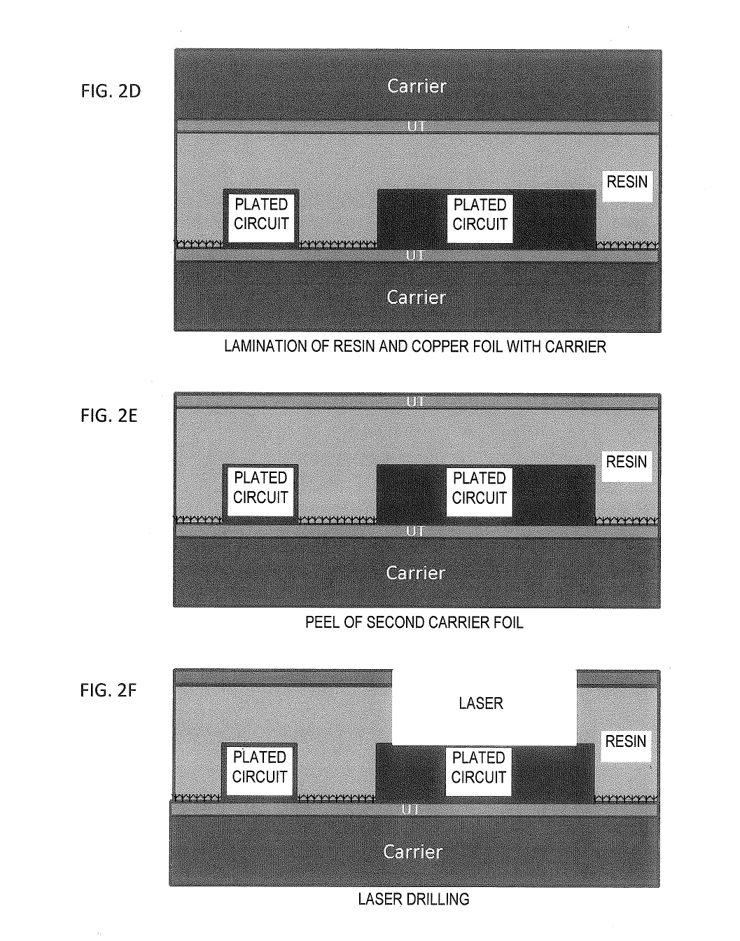

Next, as shown in FIG. 2D, a resin for embedding is disposed on the ultra-thin copper layer such that the plated circuit is covered (such that the plated circuit is embedded), and a resin layer is laminated thereon. The ultra-thin copper layer of a second copper foil with a carrier (second layer) is then bonded.

Next, as shown in FIG. 2-E, the carrier is peeled from the second copper foil with a carrier.

Next, as shown in FIG. 2-F, predetermined positions of the resin layer are drilled with laser beams to expose the plated circuit and form blind via holes.

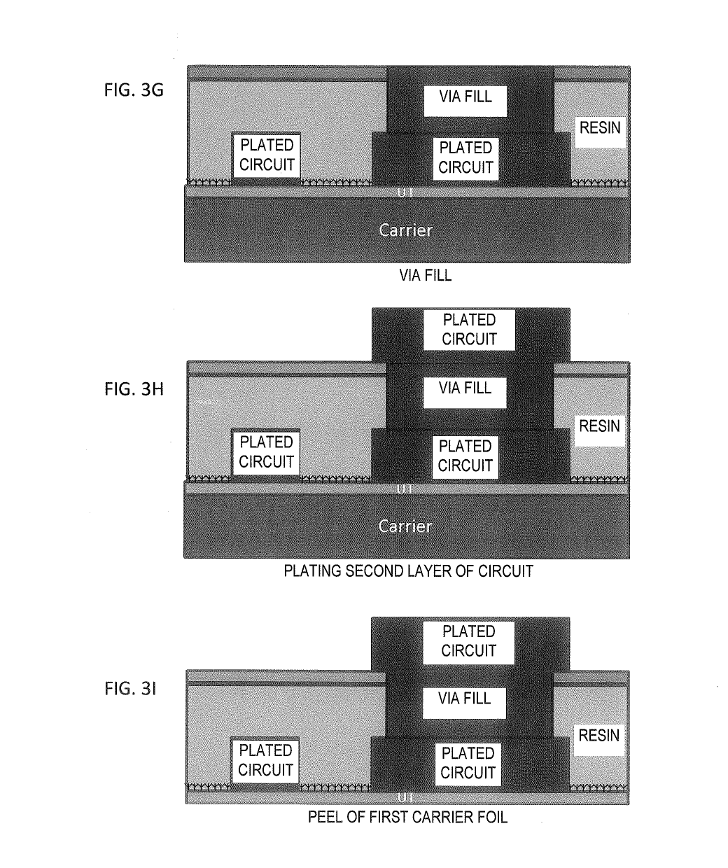

Next, as shown in FIG. 3-G, copper is buried into the blind via holes to form a buried via fill.

Next, as shown in FIG. 3-H, a plated circuit is formed on the via fill in such a way in FIGS. 1-B and 1-C.

Next, as shown in FIG. 3-I, the carrier is peeled from the first copper foil with a carrier.

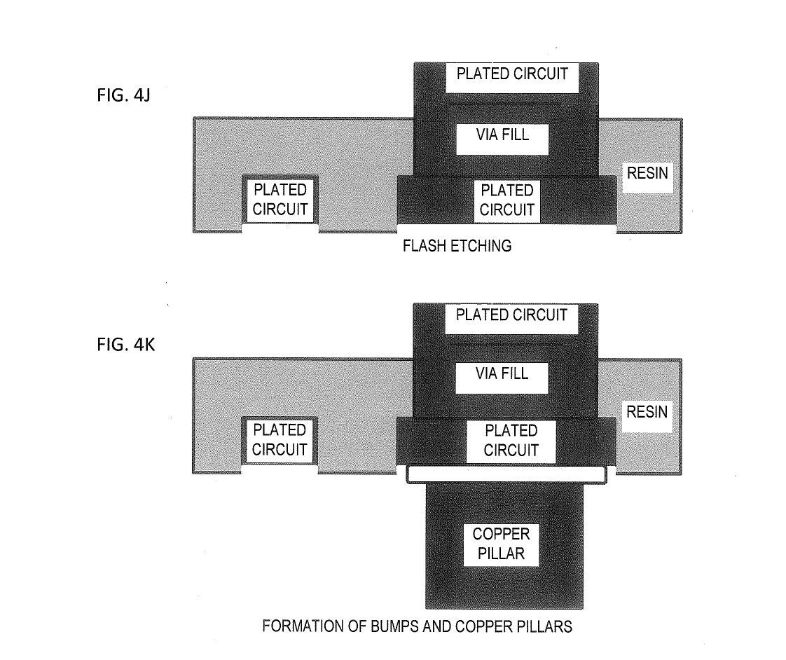

Next, as shown in FIG. 4-J, the ultra-thin copper layer on both surfaces is removed by flash etching to expose the surface of the plated circuit under the resin layer.

Next, as shown in FIG. 4-K, bumps are formed on the plated circuit exposed from the resin layer, and copper pillars are formed on the solder. A printed wiring board using the copper foil with a carrier according to the present invention is thereby prepared.

In the method of producing a printed wiring board described above, the “ultra-thin copper layer” can be replaced with the carrier and the “carrier” can be replaced with the ultra-thin copper layer. A circuit can be formed on the surface close to the carrier of a copper foil with a carrier, and can be buried with a resin to produce a printed wiring board.

In the embedding process described above using the copper foil with a carrier according to the present invention, etching of the ultra-thin copper layer to expose the buried circuit is completed in a short time because of its very small thickness, significantly enhancing the productivity.

The second copper foil with a carrier (second layer) may be the copper foil with a carrier according to the present invention, may be a conventional copper foil with a carrier, or may be a common copper foil. A mono- or multi-layer of circuit may be further formed on the circuit of the second copper foil with a carrier as shown in FIG. 3-H by one of the semi-additive process, the subtractive process, the partly additive process, and the modified semi-additive process.

In the semi-additive process or the modified semi-additive process using the copper foil with a carrier according to the present invention, flash etching of the ultra-thin copper layer is completed in a short time because of its very small thickness, significantly enhancing the productivity.

The first copper foil with a carrier used as the first layer may have a substrate on the surface close to the carrier of the copper foil with a carrier. The first copper foil with a carrier is supported by the substrate to prevent wrinkles, advantageously enhancing the productivity. Any substrate can be used as long as the substrate can support the first copper foil with a carrier. Examples of usable substrates include the carrier, the prepreg, and the resin layer described in this specification, and known carriers, prepregs, resin layers, metal plates, metal foils, inorganic compound plates, inorganic compound foils, organic compound plates, and organic compound foils.

Although the substrate can be formed on the surface close to the carrier of the copper foil with a carrier at any timing, the substrate should be formed before peeling of the carrier. In particular, the substrate is formed preferably before the step of forming the resin layer on the surface close to the ultra-thin copper layer of the copper foil with a carrier, more preferably before the step of forming a circuit on the surface close to the ultra-thin copper layer of the copper foil with a carrier.

Known resins and prepregs can be used as the resin for embedding (resin). For example, a prepreg or a glass cloth impregnated with a bismaleimide triazine (BT) resin or a BT resin, or an ABF film manufactured by Ajinomoto Fine-Techno Co., Inc., or ABF can be used. The resin for embedding may contain a thermosetting resin, or may be a thermoplastic resin. The resin layer and/or the resin and/or the prepreg and/or the film described in this specification can also be used as the resin for embedding (resin).

Electronic parts are then mounted on the printed wiring board according to the present invention to finish a printed circuit board. In the present invention, the “printed wiring board” also includes printed wiring boards, printed circuit boards, and printed substrates on which electronic parts are mounted.

Moreover, the printed wiring board may be used to produce electronic devices. The printed circuit boards having electronic parts mounted thereon may be used to produce electronic devices. The printed substrates having electronic parts mounted thereon may be used to produce electronic devices.

The method of producing a printed wiring board according to the present invention may be a method of producing a printed wiring board (coreless process), comprising a step of laminating the surface close to the ultra-thin copper layer or the carrier of the copper foil with a carrier according to the present invention on a resin substrate, a step of disposing at least one layer group composed of a resin layer and a circuit on the surface of the copper foil with a carrier opposite to the surface close to the ultra-thin copper layer or the carrier thereof laminated on the resin substrate, and a step of peeling the carrier or the ultra-thin copper layer from the copper foil with a carrier after formation of the at least one layer group composed of a resin layer and a circuit. In a specific example of the coreless process, first, the surface close to the ultra-thin copper layer or the carrier of one copper foil with a carrier according to the present invention is laminated on a resin substrate to prepare a laminate (also referred to as copper clad laminate board or copper clad laminate). Subsequently, a resin layer is formed on the surface of the copper foil with a carrier opposite to the surface close to the ultra-thin copper layer or the carrier thereof laminated on the resin substrate. The carrier or the ultra-thin copper layer of another copper foil with a carrier may be laminated on the resin layer formed on the surface close to the carrier or the ultra-thin copper layer of the copper foil with a carrier.

In the method of producing a printed wiring board (coreless process), a copper foil with a carrier of a laminate having the following configuration may be used: a laminate of carrier/intermediate layer/ultra-thin copper layer in this order or ultra-thin copper layer/intermediate layer/carrier in this order on both surfaces of a resin substrate as a core, a laminate of “carrier/intermediate layer/ultra-thin copper layer/resin substrate/ultra-thin copper layer/intermediate layer/carrier” in this order on both surfaces of a resin substrate as a core, a laminate of “carrier/intermediate layer/ultra-thin copper layer/resin substrate/carrier/intermediate layer/ultra-thin copper layer” in this order on both surfaces of a resin substrate as a core, or a laminate of “ultra-thin copper layer/intermediate layer/carrier/resin substrate/carrier/intermediate layer/ultra-thin copper layer” in this order on both surfaces of a resin substrate as a core.

Another resin layer may be disposed on the exposed surfaces of the ultra-thin copper layers or the carriers on both ends. A copper layer or a metal layer may be disposed, and may be then processed to form a circuit. A different resin layer may be further disposed on the circuit such that the circuit is buried. Formation of such a circuit and such a resin layer may be performed more than once (build-up process). The ultra-thin copper layer or the carrier of each copper foil with a carrier in the resulting laminate (hereinafter, also referred to as laminate B) can be peeled from the carrier or the ultra-thin copper layer to prepare a coreless substrate. In preparation of the coreless substrate described above, two copper foils with a carrier may be used to prepare a laminate of ultra-thin copper layer/intermediate layer/carrier/carrier/intermediate layer/ultra-thin copper layer described later, a laminate of carrier/intermediate layer/ultra-thin copper layer/ultra-thin copper layer/intermediate layer/carrier, or a laminate of carrier/intermediate layer/ultra-thin copper layer/carrier/intermediate layer/ultra-thin copper layer, and the laminate can also be used as a core. At least one layer group composed of a resin layer and a circuit can be disposed on the surfaces of the ultra-thin copper layer or the carrier on both ends of the laminate (hereinafter, also referred to as laminate A), and the ultra-thin copper layer or the carrier of each copper foil with a carrier can be then peeled from the carrier or the ultra-thin copper layer to prepare a coreless substrate. The laminate may have an additional layer on the surface of the ultra-thin copper layer, the surface of the carrier, between the carriers, between the ultra-thin copper layers, or between the ultra-thin copper layer and the carrier. The additional layer may be a resin layer or a resin substrate. Through this specification, the terms “surface of the ultra-thin copper layer,” “surface close to the ultra-thin copper layer,” “surface of the carrier,” “surface close to the carrier,” “surface of the laminate,” and “laminate surface” indicate concepts including the surface (outer surface) of the additional layer when the ultra-thin copper layer, the carrier or the laminate has an additional layer on the surface of the ultra-thin copper layer, the surface of the carrier or the surface of the laminate, respectively. The laminate preferably has a configuration of ultra-thin copper layer/intermediate layer/carrier/carrier/intermediate layer/ultra-thin copper layer. This is because the ultra-thin copper layer is disposed on the coreless substrate in preparation of a coreless substrate using the laminate; as a result, a circuit is readily formed on the coreless substrate by the modified semi-additive process. The ultra-thin copper layer is readily removed because of its small thickness. As a result, a circuit is readily formed on the coreless substrate by the semi-additive process after removal of the ultra-thin copper layer.

Through this specification, the terms “laminate A,” “laminate B,” and “laminate” without a symbol indicate a laminate including at least laminate A and laminate B.

In the method of producing a coreless substrate, end surfaces of the copper foil with a carrier or the laminate (laminate A) can be partially or completely covered with a resin to prevent elution of a chemical solution into the intermediate layer or between one copper foil with a carrier and the other copper foil with a carrier forming the laminate during production of the printed wiring board by the build-up process. As a result, separation of the ultra-thin copper layer from the carrier caused by elution of the chemical solution or corrosion of the copper foil with a carrier can be prevented, enhancing the yield. The “resin for partially or completely covering end surfaces of the copper foil with a carrier” or the “resin for partially or completely covering end surfaces of the laminate” used here can be a resin used as the resin layer. In the method of producing a coreless substrate, when the copper foil with a carrier or the laminate is seen in planar view, at least part of the outer periphery of the laminated portion of the copper foil with a carrier or the laminate (laminated portion of the carrier and the ultra-thin copper layer or the laminated portion of one copper foil with a carrier and the other copper foil with a carrier) may be covered with a resin or a prepreg. The laminate formed by the method of producing a coreless substrate (laminate A) may be composed of a pair of copper foils with a carrier in separable contact with each other. When the copper foil with a carrier is seen in planar view, the entire outer periphery of the laminated portion of the copper foil with a carrier or the laminate (laminated portion of the carrier and the ultra-thin copper layer or the laminated portion of one copper foil with a carrier and the other copper foil with a carrier) may be covered with a resin or a prepreg. When seen in planar view, the resin or the prepreg is preferably larger than the copper foil with a carrier or the laminate or the laminated portion of the laminate. A preferred laminate has a configuration in which the resin or the prepreg is laminated on both surfaces of the copper foil with a carrier or the laminate to enclose (wrap) the copper foil with a carrier or the laminate with the resin or the prepreg. In such a configuration, the laminated portion of the copper foil with a carrier or the laminate can be covered with the resin or the prepreg when the copper foil with a carrier or the laminate is seen in planar view, preventing crash of other members into the laminated portion from the lateral direction, namely, the direction lateral to the lamination direction. As a result, peeling between the carrier and the ultra-thin copper layer or between the copper foils with a carrier during handling can be reduced. The outer periphery of the laminated portion of the copper foil with a carrier or the laminate is covered with the resin or the prepreg so as not to be exposed. As a result, elution of the chemical solution into the interface of the laminated portion during a treatment with a chemical solution can be prevented, thus preventing corrosion or erosion of the copper foil with a carrier. In separation of one copper foil with a carrier from a pair of the copper foils with a carrier forming the laminate or separation of the carrier from the copper foil (ultra-thin copper layer) of the copper foil with a carrier, the laminated portion may be removed by cutting if the laminated portion of the copper foil with a carrier or the laminate (laminated portion of the carrier and the ultra-thin copper layer or the laminated portion of one copper foil with a carrier and the other copper foil with a carrier) covered with the resin or the prepreg firmly adheres to the resin or the prepreg.

The surface close to the carrier or the ultra-thin copper layer of one copper foil with a carrier according to the present invention may be laminated on the surface close to the carrier or the ultra-thin copper layer of another copper foil with a carrier according to the present invention to form a laminate. Alternatively, the surface close to the carrier or the ultra-thin copper layer of one copper foil with a carrier and the surface close to the carrier or the ultra-thin copper layer of the other copper foil with a carrier may be directly laminated when necessary with an adhesive to form a laminate. The carrier or the ultra-thin copper layer of one copper foil with a carrier and the carrier or the ultra-thin copper layer of the other copper foil with a carrier may be joined. Here, the term “join” includes embodiments in which the carrier and the ultra-thin copper layer are joined to each other through the surface treated layer, if the surface treated layer is included in the carrier or the ultra-thin copper layer. End surfaces of the laminate may be partially or completely covered with a resin.

Carriers, ultra-thin copper layers, a carrier and an ultra-thin copper layer, and copper foils with a carrier can be laminated through simple layering, or by one of the following methods, for example:
(a) metallurgical joining: fusion welding (arc welding, tungsten inert gas (TIG) welding, metal inert gas (MIG) welding, resistance welding, seam welding, spot welding), pressure welding (ultrasonic welding, friction stir welding), brazing and soldering;
(b) mechanical joining: joining with caulking and rivets (joining with self-piercing rivets, joining with rivets), stitcher; and
(c) physical joining: adhesives, (double-sided) adhesive tapes.

Part or all of one carrier can be joined to part or all of the other carrier or part or all of the ultra-thin copper layer by the joining method to laminate the one carrier and the other carrier or the ultra-thin copper layer. A laminate composed of the carriers or the carrier and the ultra-thin copper layer in separable contact with each other can be thereby produced. When one carrier is weakly joined to the other carrier or the ultra-thin copper layer in the laminate of the one carrier and the other carrier or the ultra-thin copper layer, the one carrier is separable from the other carrier or the ultra-thin copper layer without removing the joint portion between the one carrier and the other carrier or the ultra-thin copper layer. When the one carrier is firmly joined to the other carrier or the ultra-thin copper layer, the one carrier can be separated from the other carrier or the ultra-thin copper layer through cutting, chemical polishing (such as etching), or mechanical polishing of the joint portion between the one carrier and the other carrier.

The resulting laminate can be subjected to a step of disposing at least one layer group composed of a resin layer and a circuit, and a step of peeling the ultra-thin copper layer or the carrier from the copper foil with a carrier of the laminate after formation of the at least one layer group composed of a resin layer and a circuit. A printed wiring board can be thereby prepared. The at least one layer group composed of a resin layer and a circuit may be disposed on one or both surfaces of the laminate.

The resin substrate, the resin layer, the resin, and the prepreg used in the laminate described above may be the resin layer described in this specification, and may contain the resin, the resin curing agent, the compound, the curing accelerator, the dielectric substance, the reaction catalyst, the crosslinking agent, the polymer, the prepreg, and the skeleton material used in the resin layer described in this specification. The copper foil with a carrier may be smaller than the resin or the prepreg when seen in planar view.

<Method of Producing Copper Foil with Carrier>

The method of producing the copper foil with a carrier according to the present invention will now be described. The copper foil with a carrier according to the present invention should be produced on the following conditions:
(1) While the carrier supported by the drum is being conveyed by a roll-to-roll conveying method, the intermediate layer (also referred to as releasing layer) and the ultra-thin copper layer are formed by electrolytic plating. Alternatively, conveying rolls are disposed in a short distance in a production apparatus used in formation of the ultra-thin copper layer, and the conveying tension is set about 3 to 5 times that usually used to form an ultra-thin copper layer.

In control of the thickness of the extremely thin copper foil according to the present invention to 0.9 μm or less, the current density during plating is controlled to 10 A/dm² or more to increase the current density during plating. A current density of 10 A/dm² or less causes powdery plating, resulting in a poor plated surface. The current density is preferably 10 A/dm² or more, more preferably 12 A/dm² or more, still more preferably 15 A/dm² or more.

In control of the releasing strength of the extremely thin copper foil according to the present invention to 10 N/m or less, the temperature of the treatment solution during formation of the intermediate layer (such as the temperature of the plating solution used in Cr, Ni, or Co—Mo plating, or the temperature of the chromate treatment solution or the treatment solution used in formation of an organic product layer) is controlled in the range of 45 to 70° C. If the temperature of the plating solution during formation of the intermediate layer or the temperature of the treatment solution is less than 45° C., the reaction rate is reduced to readily increase the releasing strength. As a result, control of the releasing strength to 10 N/m or less is difficult. If the temperature of the plating solution during formation of the intermediate layer or the temperature of the treatment solution is more than 70° C., uneven plating or an uneven treatment layer is produced, resulting in a poor appearance. The temperature of the plating solution during formation of the intermediate layer or the temperature of the treatment solution is preferably 45 to 70° C., more preferably 50 to 65° C., still more preferably 55 to 60° C.

### About (1):

In the method of producing the copper foil with a carrier according to one embodiment of the present invention, the surface of the elongate carrier conveyed in the length direction by a roll-to-roll conveying method is treated to produce a copper foil with a carrier including a carrier, an intermediate layer laminated on the carrier, and an ultra-thin copper layer laminated on the intermediate layer. The method of producing the copper foil with a carrier according to one embodiment of the present invention comprises a step of forming an intermediate layer on the surface of a carrier by plating (such as wet plating such as electrolytic plating and non-electrolytic plating, and dry plating such as sputtering, CVD, and PVD) while the carrier conveyed with conveying rolls is being supported by a drum, a step of forming an ultra-thin copper layer on the surface of the intermediate layer by plating (such as wet plating such as electrolytic plating and non-electrolytic plating, and dry plating such as sputtering, CVD, and PVD) while the carrier having the intermediate layer formed thereon is being supported by the drum, and a step of forming a roughened layer on the surface of the ultra-thin copper layer by plating (such as wet plating such as electrolytic plating and non-electrolytic plating, and dry plating such as sputtering, CVD, and PVD) while the carrier is being supported by the drum. For example, the treated surface of the carrier supported by the drum serves as a cathode in these steps, and electrolytic plating is performed between the drum and an anode disposed facing the drum in a plating solution. Thus, the distance between the anode and the cathode in plating is stabilized through formation of the intermediate layer and the ultra-thin copper layer by plating (such as wet plating such as electrolytic plating and non-electrolytic plating, and dry plating such as sputtering, CVD, and PVD) while the carrier supported by the drum is being conveyed by the roll-to-roll method. For this reason, a fluctuation in thickness of the resulting layer can be preferably reduced to prepare the extremely thin copper layer according to the present invention with high precision. Such a stable distance between the anode and the cathode in plating preferably reduces a fluctuation in thickness of the intermediate layer formed on the surface of the carrier, and hence prevents diffusion of Cu from the carrier to the ultra-thin copper layer. As a result, generation of pin holes in the ultra-thin copper layer is preferably prevented.

Examples of the method of producing the copper foil with a carrier according to one embodiment of the present invention other than the method of supporting the carrier by the drum include a method of disposing conveying rolls in a short distance in a production apparatus used in formation of the ultra-thin copper layer, and setting the conveying tension about 3 to 5 times that usually used to form an ultra-thin copper layer. Conveying rolls disposed in a short distance (for example, about 800 to 1000 mm) through introduction of a support roll or the like and a conveying tension set about 3 to 5 times that usually used result in stable positioning of the carrier and a stable distance between the anode and the cathode. Such a stable distance between the anode and the cathode enables a shorter distance between the anode and the cathode than that usually used.

Use of sputtering or non-electrolytic plating rather than the drum method increases production cost because of high running cost of the apparatus and high cost of the sputtering target and chemical solutions for the plating solution.

### EXAMPLES

The present invention will be now described in more detail by way of Examples of the present invention, but the present invention will not be limited to these Examples.
1. Production of Copper Foil with Carrier

A copper foil having a thickness shown in Table 1 was provided as a carrier. In the table, “Electrodeposited copper foil” represents an electrodeposited copper foil manufactured by JX Nippon Mining & Metals Corporation, and “Rolled copper foil” represents a tough-pitch copper foil (JIS-H3100-C1100) manufactured by JX Nippon Mining & Metals Corporation.

The shiny surface of the copper foil was subjected to a treatment on a roll-to-roll continuous plating line on the following conditions to form the intermediate layer, the ultra-thin copper layer, and the roughened layer shown in the table.

### (Formation of Intermediate Layer)

The intermediate layer was formed under the conditions shown in Table 1.
Current density during formation of intermediate layer

The intermediate layer was formed at a current density shown in Table 1, in which the symbols therefor represent the following conditions:

double circle: 15 A/dm² or more

circle: 10 A/dm² or more and less than 15 A/dm²

X-mark: less than 10 A/dm²

### —Temperature During Formation of Intermediate Layer—

The intermediate layer was formed at a temperature of the treatment solution shown in Table 1, in which symbols each represent the following conditions:

double circle: 50° C. or more and 65° C. or less

circle: 40° C. or more and less than 50° C. or more than 65° C. and 70° C. or less

X-mark: less than 40° C. or more than 70° C.

### —Method of Forming Intermediate Layer—

The method of forming an intermediate layer shown in Table 1 was performed on the following conditions.

### (A) Method of Conveying Foil on Drum

Anode: insoluble electrode
Cathode: surface of a carrier supported by a drum having a diameter of 100 cm
Distance between anode and cathode: 10 mm
Tension of carrier conveyed: 0.05 kg/mm

### (B) Improved Method of Conveying Foil in Zigzag Manner

Anode: insoluble electrode
Cathode: treated surface of carrier
Distance between anode and cathode: 10 mm
Tension of carrier conveyed: 0.20 kg/mm
A support roll was disposed between conveying rolls to set the distance between the rolls to about 800 to 1000 mm, that is, ½ of a typical distance between conveying rolls during formation of the ultra-thin copper layer.

Inputs in “Intermediate layer” in the table represent the treatments performed. For example, an input “Ni/organic product” indicates that a nickel plating treatment is performed, followed by an organic treatment.
“Ni”: nickel plating
(Composition of solution) nickel sulfate: 270 to 280 g/L, nickel chloride: 35 to 45 g/L, nickel acetate: 10 to 20 g/L, trisodium citrate: 15 to 25 g/L, gloss agent: saccharin, butynediol, or the like, sodium dodecyl sulfate: 55 to 75 ppm
(pH) 4 to 6
(Time of electric conduction) 1 to 20 seconds
   “Chromate”: pure chromate electrolytic treatment (Composition of solution) potassium bichromate: 1 to 10 g/L
(pH) 7 to 10
(Amount of Coulomb) 0.5 to 90 As/dm²
(Time of electric conduction) 1 to 30 seconds
   “Organic product”: organic product layer forming treatment

An aqueous solution of 1 to 30 g/L of carboxybenzotriazole (CBTA) having a solution temperature of 40° C. and a pH of 5 was sprayed by showering for 20 to 120 seconds to perform a treatment.
“Ni—Mo”: nickel molybdenum alloy plating
(Composition of solution) nickel sulfate hexahydrate: 50 g/dm³, sodium molybdate dihydrate: 60 g/dm³, sodium citrate: 90 g/dm³
(Time of electric conduction) 3 to 25 seconds
   “Cr”: chromium plating
(Composition of solution) CrO₃: 200 to 400 g/L, H₂SO₄: 1.5 to 4 g/L
(pH) 1 to 4
(Time of electric conduction) 1 to 20 seconds
   “Co—Mo”: cobalt molybdenum alloy plating
(Composition of solution) cobalt sulfate: 50 g/dm³, sodium molybdate dihydrate: 60 g/dm³, sodium citrate: 90 g/dm³
(Time of electric conduction) 3 to 25 seconds
   “Ni—P”: nickel phosphorus alloy plating
(Composition of solution) Ni: 30 to 70 g/L, P: 0.2 to 1.2 g/L
(pH) 1.5 to 2.5
(Time of electric conduction) 0.5 to 30 seconds

### (Formation of Ultra-Thin Copper Layer)

The method of forming an ultra-thin copper layer shown in Table 1 was performed on the following conditions.

### (A) Method of Conveying Foil on Drum

Anode: insoluble electrode
Cathode: surface of a carrier supported by a drum having a diameter of 100 cm
Distance between anode and cathode: 10 mm
Composition of electrolyte solution: copper content of 80 to 120 g/L, sulfuric acid content of 80 to 120 g/L
Temperature of electrolytic plating bath: 50 to 80° C.
Current density in electrolytic plating: 90 A/dm²
Tension of carrier conveyed: 0.05 kg/mm

### (B) Improved Method of Conveying Foil in Zigzag Manner

Anode: insoluble electrode
Cathode: treated surface of carrier
Distance between anode and cathode: 10 mm
Composition of electrolyte solution: copper content of 80 to 120 g/L, sulfuric acid content of 80 to 120 g/L
Temperature of electrolytic plating bath: 50 to 80° C.
Current density in electrolytic plating: 90 A/dm2
Tension of carrier conveyed: 0.20 kg/mm
A support roll was disposed between conveying rolls to set the distance between the rolls to about 800 to 1000 mm, that is, ½ of a typical distance between conveying rolls during formation of the ultra-thin copper layer.

### (Formation of Roughened Layer)

The method of forming a roughened layer shown in Table 1 was performed on the following conditions.

### (A) Method of Conveying Foil on Drum

Anode: insoluble electrode
Cathode: surface of a carrier supported by a drum having a diameter of 100 cm
Distance between anode and cathode: 10 mm
Tension of carrier conveyed: 0.05 kg/mm

### (B) Improved Method of Conveying Foil in Zigzag Manner

Anode: insoluble electrode
Cathode: treated surface of carrier
Distance between anode and cathode: 10 mm
Tension of carrier conveyed: 0.20 kg/mm
A support roll was disposed between conveying rolls to set the distance between the rolls to about 800 to 1000 mm, that is, ½ of a typical distance between conveying rolls during formation of the ultra-thin copper layer.

In the table, “1” and “2” in “Conditions on formation of roughening” each represent the following treatment conditions.

### (1) Roughening Condition “1”

### (Composition of Solution)

Cu: 10 to 20 g/L

Ni: 5 to 15 g/L

Co: 5 to 15 g/L

### (Conditions on Electroplating)

Temperature: 25 to 60° C.

Current density: 35 to 55 A/dm²

Amount of Coulomb during roughening: 5 to 50 As/dm²

Plating time: 0.1 to 1.4 seconds

### (2) Roughening Condition “2”

Composition of electrolytic plating solution (Cu: 10 g/L, H₂SO₄: 50 g/L)
Temperature of electrolytic plating bath: 40° C.
Current density in electrolytic plating: 20 to 40 A/dm²
Amount of Coulomb during roughening: 2 to 56 As/dm²
Plating time: 0.1 to 1.4 seconds

### (Formation of Heat-Resistant Layer)

“Cu—Zn”: copper-zinc alloy plating

### (Composition of Solution)

NaOH: 40 to 200 g/L

NaCN: 70 to 250 g/L

CuCN: 50 to 200 g/L

Zn(CN)₂: 2 to 100 g/L

As₂O₃: 0.01 to 1 g/L

### (Solution Temperature)

40 to 90° C.

### (Conditions on Current)

Current density: 1 to 50 A/dm²

Plating time: 1 to 20 seconds

“Ni—Zn”: nickel-zinc alloy plating

Solution composition: nickel: 2 to 30 g/L, zinc: 2 to 30 g/L

pH: 3 to 4

Solution temperature: 30 to 50° C.

Current density: 1 to 2 A/dm²

Amount of Coulomb: 1 to 2 As/dm²

“Zn”: zinc plating

Solution composition: zinc: 15 to 30 g/L

pH: 3 to 4

Solution temperature: 30 to 50° C.

Current density: 1 to 2 A/dm²

Amount of Coulomb: 1 to 2 As/dm²

### (Formation of Anti-Corrosive Layer)

“Chromate”: chromate treatment

K₂Cr₂O₇ (Na₂Cr₂O₇ or CrO₃): 2 to 10 g/L

NaOH or KOH: 10 to 50 g/L

ZnOH or ZnSO₄.7H₂O: 0.05 to 10 g/L

pH: 7 to 13

Bath temperature: 20 to 80° C.

Current density: 0.05 to 5 A/dm²

Time: 5 to 30 seconds

### (Formation of Silane Coupling Treated Layer)

An aqueous solution of 0.1 vol % to 0.3 vol % of 3-glycidoxypropyltrimethoxysilane was applied by spraying, and the workpiece was dried in the air at 100 to 200° C. for 0.1 to 10 seconds with heating.

2. Evaluation of Copper Foil with Carrier

The copper foils with a carrier were evaluated by the following methods.

### <Measurement of Thickness of Ultra-Thin Copper Layer>

A copper foil with a carrier is weighed. The carrier is then peeled. The carrier is weighed. The difference between the weight of the copper foil with a carrier and that of the carrier is defined as the weight of the ultra-thin copper layer.
Size of sample: 10 cm square sheet (punched into a 10 cm square sheet with a press)
Extraction of sample: any three places

In these samples, the thickness of the ultra-thin copper layer was calculated by the weight method from the following expression:

thickness (μm) of ultra-thin copper layer determined by the weight method={(weight (g/100 cm²) of 10 cm square sheet of copper foil with carrier)−(weight (g/100 cm²) of carrier after peeling of ultra-thin copper layer from 10 cm square sheet of copper foil with carrier)}/density (8.96 g/cm³) of copper×0.01 (100 cm²/m²)×10000 μm/cm

The weight of the sample was measured with a precision balance enabling measurement to four decimal places. The resulting weight was used in the calculation above as it was.
The arithmetic average of the three thicknesses of the ultra-thin copper layer determined by the weight method was defined as the thickness of the ultra-thin copper layer determined by the weight method.

The precision balance used was a precision balance IBA-200 from AS ONE Corporation. A press HAP-12 manufactured by Noguchi Press Co., Ltd. was used.

If surface treated layers such as the roughened layer were formed on the ultra-thin copper layer, the measurement was performed after formation of the surface treated layers.

### <Measurement of Releasing Strength (Normal Releasing Strength)>

The surface close to the ultra-thin copper layer of the copper foil with a carrier was laminated to a BT resin (triazine-bismaleimide resin, manufactured by Mitsubishi Gas Chemical Company, Inc.), and was hot-pressed at 220° C. for two hours at 20 kg/cm². Next, the carrier was pulled with a tensile tester to peel the carrier according to JIS C 6471 8.1. The releasing strength at this time was measured.

### <Pin Holes>

The surface close to the ultra-thin copper layer of the copper foil with a carrier was laminated to a BT resin (triazine-bismaleimide resin, manufactured by Mitsubishi Gas Chemical Company, Inc.), and was hot-pressed at 220° C. for two hours at 20 kg/cm². Next, the resulting sample of the copper foil with a carrier was placed with the carrier facing upward, and the carrier was carefully peeled by hand from the ultra-thin copper layer while the sample was fixed by hand such that the ultra-thin copper layer was not broken halfway, rather than forcibly peeling the carrier. Subsequently, in each of five samples of 250 mm×250 mm, the surface of the ultra-thin copper layer on the BT resin (triazine-bismaleimide resin, manufactured by Mitsubishi Gas Chemical Company, Inc.) was visually observed under light from a backlight for photograph for consumer use to measure the number of pin holes having a diameter of 50 μm or less. The number of pin holes per unit area (m²) was calculated from the following expression:

the number of pin holes per unit area (m²) (pin holes/m²)=total number of pin holes measured in five samples of 250 mm×250 mm/total area of surface region observed (five samples×0.0625 m²/sample)

The pin holes were evaluated according to the following criteria:

double circle: 0 pin holes/m²

circle: 1 to 10 pin holes/m²

triangle: 11 to 20 pin holes/m²

X-mark: more than 20 pin holes/m²

### <Peeling in Post-Step After Formation of Ultra-Thin Copper Layer>

Peeling of the carrier in the post-step after formation of the ultra-thin copper layer (roughening step) was evaluated (peeled (five times or more in ten): X-mark, sometimes (one to four times in ten): triangle, none: circle).

The conditions on preparation and the results of evaluation in Examples and Comparative Examples are shown in Table 1.

TABLE 1

| | | | Current density | Temperature | | Method of | Thickness of | Method of |
|---|---|---|---|---|---|---|---|---|
| | Carrier | | during formation | during formation | | forming | ultra-thin | forming ultra- |
| | | Thickness | of intermediate | of intermediate | Intermediate | intermediate | copper | thin |
| No | Type of carrier | (μm) | layer (A/dm²) | layer (° C.) | layer | layer | layer (μm) | copper layer |
| Example 1 | Electrodeposited | 18 | ◯ | ⊚ | Ni/Chromate | A | 0.1 | A |
| | copper foil | | | | | | | |
| Example 2 | Electrodeposited | 18 | ◯ | ⊚ | Ni/Chromate | A | 0.2 | A |
| | copper foil | | | | | | | |
| Example 3 | Electrodeposited | 18 | ⊚ | ⊚ | Ni/Chromate | A | 0.3 | A |
| | copper foil | | | | | | | |
| Example 4 | Electrodeposited | 18 | ⊚ | ⊚ | Ni/Chromate | A | 0.4 | A |
| | copper foil | | | | | | | |
| Example 5 | Electrodeposited | 18 | ⊚ | ⊚ | Ni/Chromate | A | 0.5 | A |
| | copper foil | | | | | | | |
| Example 19 | Electrodeposited | 18 | ⊚ | ◯ | Ni/Chromate | A | 0.9 | A |
| | copper foil | | | | | | | |
| Example 6 | Electrodeposited | 18 | ⊚ | ⊚ | Ni/Chromate | A | 0.3 | A |
| | copper foil | | | | | | | |
| Example 7 | Electrodeposited | 18 | ⊚ | ⊚ | Ni/Chromate | A | 0.3 | A |
| | copper foil | | | | | | | |
| Example 8 | Electrodeposited | 18 | ⊚ | ⊚ | Ni/Chromate | A | 0.3 | A |
| | copper foil | | | | | | | |
| Example 9 | Electrodeposited | 18 | ⊚ | ◯ | Ni/Chromate | A | 0.3 | A |
| | copper foil | | | | | | | |
| Example 10 | Rolled copper foil | 18 | ⊚ | ◯ | Ni/Chromate | A | 0.3 | A |
| Example 11 | Electrodeposited | 35 | ⊚ | ⊚ | Ni/Chromate | A | 0.3 | A |
| | copper foil | | | | | | | |
| Example 12 | Electrodeposited | 12 | ⊚ | ⊚ | Ni/Chromate | A | 0.3 | A |
| | copper foil | | | | | | | |
| Example 13 | Electrodeposited | 70 | ⊚ | ⊚ | Ni/Chromate | A | 0.3 | A |
| | copper foil | | | | | | | |
| Example 14 | Electrodeposited | 18 | ⊚ | ◯ | Ni/Organic | A | 0.3 | A |
| | copper foil | | | | product | | | |
| Example 15 | Electrodeposited | 18 | ⊚ | ⊚ | Ni—Mo | A | 0.3 | A |
| | copper foil | | | | | | | |
| Example 16 | Electrodeposited | 18 | ⊚ | ⊚ | Cr | A | 0.3 | A |
| | copper foil | | | | | | | |
| Example 17 | Electrodeposited | 18 | ⊚ | ⊚ | Co—Mo | A | 0.3 | A |
| | copper foil | | | | | | | |
| Example 18 | Electrodeposited | 18 | ⊚ | ⊚ | Ni—P | B | 0.3 | B |
| | copper foil | | | | | | | |
| Comparative | Electrodeposited | 18 | X | ◯ | Ni/Chromate | A | 0.1 | A |
| Example 1 | copper foil | | | | | | | |
| Comparative | Electrodeposited | 18 | X | ◯ | Ni/Chromate | A | 0.3 | A |
| Example 2 | copper foil | | | | | | | |
| Comparative | Electrodeposited | 18 | X | X | Ni/Chromate | A | 0.9 | A |
| Example 3 | copper foil | | | | | | | |
| Comparative | Electrodeposited | 18 | X | X | Ni/Chromate | A | 0.5 | A |
| Example 4 | copper foil | | | | | | | |
| Comparative | Electrodeposited | 18 | X | X | Ni/Chromate | A | 0.9 | A |
| Example 5 | copper foil | | | | | | | |
| Comparative | Electrodeposited | 18 | X | X | Ni/Chromate | A | 0.5 | A |
| Example 6 | copper foil | | | | | | | |
| | | | | | Silane | Normal | Pin | Peeling in post-step |
| | Method of | Conditions on | Heat- | Anti- | coupling | releasing | holes | after formation |
| | forming | formation | resistant | corrosive | treated | strength | (50 μm | of ultra-thin |
| No | roughening | of roughening | layer | layer | layer | (N/m) | or less) | copper layer |
| Example 1 | A | — | Ni—Zn | Disposed | Disposed | 5.0 | ⊚ | ◯ |
| Example 2 | A | 1 | — | — | — | 5.0 | ⊚ | ◯ |
| Example 3 | A | — | Ni—Zn | — | — | 5.0 | ⊚ | ◯ |
| Example 4 | A | 2 | Zn | Disposed | Disposed | 5.0 | ⊚ | ◯ |
| Example 5 | A | — | Cu—Zn | Disposed | — | 5.0 | ⊚ | ◯ |
| Example 19 | A | — | — | — | Disposed | 5.0 | ⊚ | ◯ |
| Example 6 | A | — | — | — | — | 3.0 | ⊚ | ◯ |
| Example 7 | A | 1 | Cu—Zn | Disposed | Disposed | 2.0 | ⊚ | Δ |
| Example 8 | A | — | — | Disposed | — | 7.5 | ⊚ | ◯ |
| Example 9 | A | — | — | Disposed | Disposed | 10.0 | ◯ | ◯ |
| Example 10 | A | 2 | Ni—Zn | Disposed | Disposed | 5.0 | ⊚ | ◯ |
| Example 11 | A | 1 | — | Disposed | Disposed | 5.0 | ⊚ | ◯ |
| Example 12 | A | 2 | Zn | Disposed | Disposed | 5.0 | ⊚ | ◯ |
| Example 13 | A | 1 | Ni—Zn | — | Disposed | 5.0 | ⊚ | ◯ |
| Example 14 | A | 1 | Ni—Zn | Disposed | — | 5.0 | ⊚ | ◯ |
| Example 15 | A | 1 | — | Disposed | — | 5.0 | ⊚ | ◯ |
| Example 16 | A | 1 | — | Disposed | Disposed | 5.0 | ⊚ | ◯ |
| Example 17 | A | 1 | — | — | Disposed | 5.0 | ⊚ | ◯ |
| Example 18 | B | 1 | Cu—Zn | — | — | 5.0 | ⊚ | ◯ |
| Comparative | A | 1 | Ni—Zn | Disposed | Disposed | 11.0 | X | ◯ |
| Example 1 | | | | | | | | |
| Comparative | A | 1 | Ni—Zn | Disposed | Disposed | 11.0 | X | ◯ |
| Example 2 | | | | | | | | |
| Comparative | A | 1 | Ni—Zn | Disposed | Disposed | 11.0 | Δ | ◯ |
| Example 3 | | | | | | | | |
| Comparative | A | 1 | Ni—Zn | Disposed | Disposed | 15.0 | X | ◯ |
| Example 4 | | | | | | | | |
| Comparative | A | 1 | Ni—Zn | Disposed | Disposed | 15.0 | X | ◯ |
| Example 5 | | | | | | | | |
| Comparative | A | 1 | Ni—Zn | Disposed | Disposed | 11.0 | X | ◯ |
| Example 6 | | | | | | | | |

### (Results of Evaluation)

In Examples 1 to 19, generation of pin holes during peeling of the carrier was able to be preferably prevented in all of the copper foils with a carrier including an ultra-thin copper layer having a thickness of 0.9 μm or less.

In Comparative Examples 1 to 6, generation of pin holes during peeling of the carrier was not able to be preferably prevented in all of the copper foils with a carrier including an ultra-thin copper layer having a thickness of 0.9 μm or less because the releasing strength during peeling of the carrier by the 90° releasing method according to JIS C 6471 8.1 exceeded 10 N/m.

What is claimed is:

1. A copper foil with a carrier, comprising a carrier, an intermediate layer, and an ultra-thin copper layer in this order,
wherein the ultra-thin copper layer has a thickness of 0.9 μm or less, and
the releasing strength during peeling of the carrier by a 90° releasing method according to JIS C 6471 8.1 is 10 N/m or less.

2. The copper foil with a carrier according to claim 1,
wherein the releasing strength during peeling of the carrier by a 90° releasing method according to JIS C 6471 8.1 is 3 to 10 N/m.

3. The copper foil with a carrier according to claim 1,
wherein the releasing strength during peeling of the carrier by a 90° releasing method according to JIS C 6471 8.1 is 3 to 9 N/m.

4. The copper foil with a carrier according to claim 1,
wherein the releasing strength during peeling of the carrier by a 90° releasing method according to JIS C 6471 8.1 is 3 to 8 N/m.

5. The copper foil with a carrier according to claim 1,
wherein the ultra-thin copper layer has a thickness of 0.05 to 0.9 μm.

6. The copper foil with a carrier according to claim 1,
wherein the ultra-thin copper layer has a thickness of 0.1 to 0.9 μm.

7. The copper foil with a carrier according to claim 1,
wherein the ultra-thin copper layer has a thickness of 0.85 μm or less.

8. The copper foil with a carrier according to claim 1,
wherein the number of pin holes per unit area (m²) of the ultra-thin copper layer (pin holes/m²) is 20 pin holes/m² or less.

9. The copper foil with a carrier according to claim 1,
wherein if the ultra-thin copper layer is disposed on one surface of the carrier in a copper foil with a carrier according to claim 1, one or more layers selected from the group consisting of a roughened layer, a heat-resistant layer, an anti-corrosive layer, a chromate treated layer, and a silane coupling treated layer are disposed on one surface or both surfaces close to the ultra-thin copper layer and close to the carrier,
or if the ultra-thin copper layer is disposed on both surfaces of the carrier in a copper foil with a carrier according to claim 1, one or more layers selected from the group consisting of a roughened layer, a heat-resistant layer, an anti-corrosive layer, a chromate treated layer, and a silane coupling treated layer are disposed on the surface of the ultra-thin copper layer on at least one of both surfaces.

10. The copper foil with a carrier according to claim 9,
wherein at least one of the anti-corrosive layer and the heat-resistant layer contains one or more elements selected from nickel, cobalt, copper, and zinc.

11. The copper foil with a carrier according to claim 1,
wherein the ultra-thin copper layer has a resin layer thereon.

12. The copper foil with a carrier according to claim 9,
wherein the one or more layers selected from a roughened layer, a heat-resistant layer, an anti-corrosive layer, a chromate treated layer, and a silane coupling treated layer have a resin layer thereon.

13. The copper foil with a carrier according to claim 11,
wherein the resin layer contains a dielectric substance.

14. The copper foil with a carrier according to claim 12,
wherein the resin layer contains a dielectric substance.

15. A method of producing a printed wiring board using a copper foil with a carrier according to claim 1.

16. A method of producing a laminate using a copper foil with a carrier according to claim 1.

17. A laminate comprising a copper foil with a carrier according to claim 1 and a resin, wherein end surfaces of the copper foil with a carrier are partially or completely covered with the resin.

18. A laminate comprising two copper foils with a carrier according to claim 1, wherein the carrier or the ultra-thin copper layer of one of the copper foils with a carrier is laminated on the carrier or the ultra-thin copper layer of the other copper foil with a carrier.

19. A method of producing a printed wiring board using a laminate according to claim 16.

20. A method of producing a printed wiring board, comprising:
a step of disposing at least one layer group composed of a resin layer and a circuit on a laminate according to claim 16, and,
a step of peeling the ultra-thin copper layer or the carrier from the copper foil with a carrier of the laminate after formation of the at least one layer group composed of a resin layer and a circuit.

21. A method of producing a printed wiring board, comprising:
a step of providing a copper foil with a carrier according to claim 1 and an insulating substrate,
a step of laminating the copper foil with a carrier on the insulating substrate,
a step of peeling the copper carrier of the copper foil with a carrier to form a copper clad laminate board after lamination of the copper foil with a carrier on the insulating substrate, and
a step of then forming a circuit by one of a semi-additive process, a subtractive process, a partly additive process, and a modified semi-additive process.

22. A method of producing a printed wiring board, comprising:
a step of forming a circuit on the surface close to the ultra-thin copper layer or the carrier of a copper foil with a carrier according to claim 1,
a step of forming a resin layer on the surface close to the ultra-thin copper layer or the carrier of the copper foil with a carrier such that the circuit is embedded,
a step of peeling the carrier or the ultra-thin copper layer, and
a step of removing the ultra-thin copper layer or the carrier after peeling of the carrier or the ultra-thin copper layer to expose the circuit formed on the surface close to the ultra-thin copper layer or the carrier of the copper foil with a carrier and embedded in the resin layer.

23. A method of producing a printed wiring board, comprising:
a step of laminating the surface close to the ultra-thin copper layer or the carrier of a copper foil with a carrier according to claim 1 on a resin substrate,
a step of disposing at least one layer group composed of a resin layer and a circuit on the surface close to the ultra-thin copper layer or the carrier of the copper foil with a carrier opposite to the surface thereof laminated on the resin substrate, and
a step of peeling the carrier or the ultra-thin copper layer from the copper foil with a carrier after formation of the at least one layer group composed of a resin layer and a circuit.

24. A method of producing an electronic device using a printed wiring board produced by a method of producing a printed wiring board according to claim 15.
